(19) United States
(12) Patent Application Publication
(10) Pub. No.: US 2012/0318976 A1
(43) Pub. Date: Dec. 20, 2012

(54) PATTERN MEASUREMENT APPARATUS AND PATTERN MEASUREMENT METHOD

(76) Inventors: Jun Matsumoto, Tokyo (JP); Hiroshi Fukaya, Tokyo (JP); Isao Yonekura, Tokyo (JP); Hidemitsu Hakii, Tokyo (JP)

(21) Appl. No.: 13/495,809

(22) Filed: Jun. 13, 2012

(30) Foreign Application Priority Data
Jun. 14, 2011 (JP) 2011-132224

(51) Int. Cl. H01J 37/26

(52) U.S. Cl. 250/307; 250/310

(57) ABSTRACT

A pattern measurement apparatus scans an observation region of a sample surface with an electron beam and detects secondary electrons emitted from the sample surface with the irradiation of the electron beam, by using a plurality of electron detectors arranged around the optical axis of the electron beam. Images are taken in two directions that are orthogonal to a pattern extending direction, and are opposite to each other across the optical axis. Then, profiles of a line orthogonal to each of edges are extracted from the images, and a subtraction between the line profiles is taken to obtain a subtractive profile. The position of an upper end of each edge is detected based on a descending portion of the subtractive profile, and the position of a lower end of the edge is detected based on a rising portion or a descending portion of one of the line profiles.

### CROSS-REFERENCE TO RELATED APPLICATIONS

This application is based upon and claims and the benefit of priority of the prior Japanese Patent Application No. 2011-132224, filed on Jun. 14, 2011, the entire contents of which are incorporated herein by reference.

### FIELD

The embodiments discussed herein are related to a pattern measurement apparatus and a pattern measurement method, and are particularly related to a pattern measurement apparatus and a pattern measurement method for measuring a shape of a pattern by scanning a sample surface with an electron beam.

### BACKGROUND

In recent years, aiming at further miniaturization and higher integration of semiconductor devices, development of new lithography techniques has been promoted such as an exposure technique using an extreme ultraviolet (EUV) light source and nanoimprint. Since these lithography techniques are required to achieve high pattern transfer accuracy, an importance is placed on management of inclination angles of edges of a mask pattern which influence the pattern transfer accuracy. Thus, manufacturing of the mask pattern requires accurate evaluation of edge inclination angles of the mask pattern.

One of methods of measuring edge inclination angles of a pattern uses a secondary electron image taken by a scanning electron microscope. In this method, a width of a band region with high brightness (white band) appearing at an edge portion of a pattern in a secondary electron image of the pattern is detected as a width of the edge. Then, an inclination angle of the edge is obtained based on the width of the white band and a known height of the pattern.

However, in this method, the width of the white band is never smaller than a diameter of a primary electron beam. When the width of the edge is smaller than the primary electron beam, the width and the inclination angle of the edge cannot be detected accurately.

There is another method in which an edge inclination angle is directly obtained by observing a cross-section of a sample with a high-resolution electron microscope. This method can obtain the edge inclination angle with high accuracy, but requires time for sample preparation, and moreover destroys the sample used for the measurement.

### SUMMARY

According to an aspect, there is provided a pattern measurement apparatus including: an electron scanner scanning an observation region of a surface of a sample with an electron beam while irradiating the observation region with the electron beam; a plurality of electron detectors arranged around an optical axis of the electron beam and detecting electrons emitted from the surface of the sample with irradiation of the electron beam; a signal processor generating a plurality of image data pieces of the observation region which are taken in different directions, on the basis of detection signals of the electron detectors; a profile creator extracting line profiles of a pattern formed on the sample from two of the image data pieces in opposite two directions across the optical axis and generating a subtractive profile of a subtraction between the line profiles extracted from the image data pieces in the two directions; and an edge detector detecting a position of an upper end of an edge of the pattern on the basis of the subtractive profile and detecting a position of a lower end of the edge on the basis of the line profile extracted from any one of the image data pieces in the two directions.

In the pattern measurement apparatus in the above aspect, the edge detector may detect the position of the lower end of the edge on the basis of the line profile extracted from the image data piece in the direction in which no shadow of the edge is generated.

In addition, the edge detector may detect a position of the minimum value of derivatives of the subtractive profile as the position of the upper end of the edge.

Moreover, according to another aspect, there is provided a pattern measurement method for detecting amounts of electrons by using a plurality of electron detectors arranged around an optical axis of the electron beam, the electrons being emitted from a surface of a sample with irradiation of an electron beam, the pattern measurement method including the steps of: generating image data pieces of the surface of the sample which are taken in a plurality of different directions on the basis of detection signals from the electron detectors; extracting line profiles of a pattern formed on the sample on the basis of two of the image data pieces in opposite two directions across the optical axis; generating a subtractive profile of a subtraction between the line profiles extracted from the image data pieces in the opposite two directions across the optical axis; detecting a position of an upper end of an edge of the pattern on the basis of the subtractive profile; and detecting a position of a lower end of the edge on the basis of the line profile extracted from any one of the image data pieces in the two directions.

According to the pattern measurement apparatus in the above aspect, the position of the upper end of the edge of the pattern is detected based on the subtraction between the two line profiles created from the image data pieces in the opposite two directions across the optical axis. This can nullify spread of a white band due to dispersion of electrons near the upper end of the edge of the pattern. Even if the width of the edge is smaller than the diameter of the primary electron beam, the position of the upper end of the edge can be obtained accurately.

In addition, the position of the lower end of the edge of the pattern is detected based on the line profile created from one of the image data pieces. Thus, the noise content can be reduced in comparison with the case of using the subtractive profile, and the position of the lower end of the edge can be detected accurately.

Thereby, the width and the inclination angle of the edge can be measured with high accuracy.

### BRIEF DESCRIPTION OF DRAWINGS

FIG. 1 is a configuration diagram of a scanning electron microscope (a pattern measuring apparatus) according to an embodiment.

FIG. 2 is a perspective diagram showing arrangement of electron detectors in FIG. 1.

FIG. 3 is a schematic diagram of image data pieces generated by a signal processor in FIG. 1.

FIG. 4 is a flowchart showing the first algorithm.

FIGS. 5A to 5D are schematic diagrams showing a relationship between signal waveforms generated based on the first algorithm and an edge of a pattern.

FIG. 6 is a schematic diagram showing influence of dispersion of secondary electrons generated near an upper end of the edge of the pattern.

FIG. 7 is a flowchart showing the second algorithm.

FIG. 8 is a schematic diagram showing a relationship among signal waveforms generated based on the second algorithm and edges of a pattern.

FIGS. 9A and 9B are diagrams showing SEM images (differential images) and subtractive profiles of samples in Experimental Example 1.

FIGS. 10A and 10B are graphs showing examples of a subtractive profile and a differential profile of the subtractive profile.

FIG. 11 is a schematic diagram for explaining why a lower end of the edge is difficult to detect in the second algorithm.

FIG. 12 is a flowchart showing the third algorithm.

FIG. 13 is a schematic diagram showing a relationship among signal waveforms generated based on the third algorithm and edges of a pattern.

FIGS. 14A and 14B are SEM images of cross-sections of first and second samples in Experimental Example 2.

FIGS. 15A and 15B are charts showing measurement results of edge inclination angles of the first sample in Experimental Example 2.

FIGS. 16A and 16B are charts showing measurement results of edge inclination angles of the second sample in Experimental Example 2.

FIG. 17 is a diagram showing subtractions between measurement results of cross-section observation and measurement results based on the first and third algorithms.

### DESCRIPTION OF EMBODIMENTS

A description is given below of an embodiment of the present invention with reference to the attached drawings.

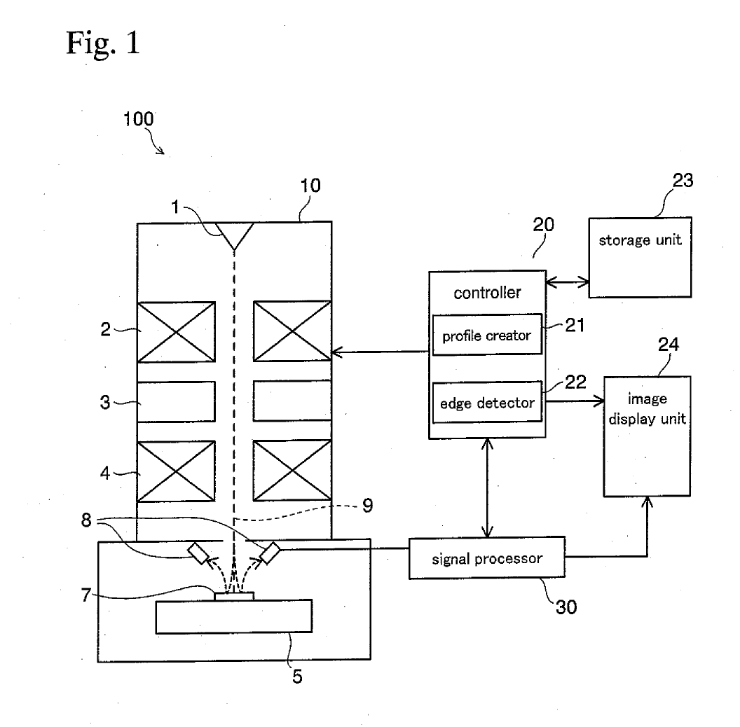

FIG. 1 is a configuration diagram of a scanning electron microscope according to the embodiment.

A scanning electron microscope 100 mainly includes an electron scanner 10, a signal processor 30, an image display unit 24, a storage unit 23, and a controller 20.

The electron scanner 10 includes an electron gun 1. The electron gun 1 emits electrons at a predetermined accelerated voltage. A condenser lens 2 focuses the electrons emitted from the electron gun 1 to form a primary electron beam 9. The electron beam 9 is deflected with a deflection coil 3, focused with an objective lens 4, and then is emitted onto a surface of a sample 7. The electron scanner 10 scans an observation region of the surface of the sample 7 with the electron beam 9 by deflecting the electron beam 9 with the deflection coil 3.

The emission of the primary electron beam 9 causes secondary electrons to be emitted from the surface of the sample 7, and the emitted secondary electrons are detected by a plurality of electron detectors 8 provided above a sample stage 5.

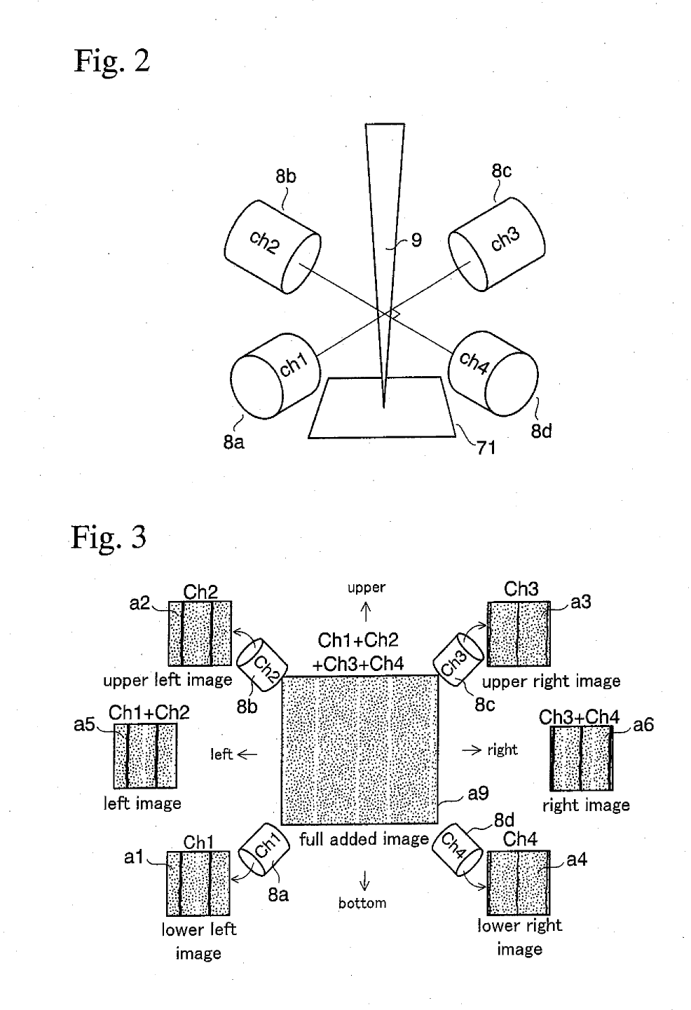

FIG. 2 is a perspective diagram showing arrangement of electron detectors 8a, 8b, 8c, and 8d.

As shown in FIG. 2, the four electron detectors 8a to 8d are herein arranged around an optical axis of the electron beam 9 at angles (90°) equal to each other. Note that the number of electron detectors is not limited to four, and may be any number of two or more.

Amounts of the secondary electrons detected by the electron detectors 8a to 8d are outputted as detection signals ch1, ch2, ch3, and ch4 to the signal processor 30 (see FIG. 1).

The signal processor 30 in FIG. 1 converts each amount of the detected secondary electrons into a digital amount by using an AD converter. Then, the signal processor 30 associates the amount of the secondary electrons and a deflection position of the primary electron beam 9 deflected by the deflection coil 3 with each other, arranges the amount and the deflection position in a two-dimensional array, and then generates an image data piece (a SEM image).

FIG. 3 shows an example of the image data pieces generated by the signal processor 30.

The signal processor 30 generates a lower left image a1, an upper left image a2, an upper right image a3, and a lower right image a4 based on the electron amounts respectively detected by the electron detectors 8a to 8d arranged in different directions. The images reflect the amounts of the secondary electrons emitted in the directions to the electron detectors 8a to 8d. Intensity values of the images vary, depending on the orientation of an edge of a pattern formed on the surface of the sample 7. Specifically, among edges facing leftward (edges having inclined surfaces whose normal lines extend in a left direction), signals from the lower left and upper left electron detectors 8a and 8b have higher brightness values than signals from the upper right and lower right electron detectors 8c and 8d. Among edges facing rightward (edges having inclined surfaces whose normal lines extend in a right direction), signals from the upper right and lower right electron detectors 8c and 8d have higher brightness values than signals from the lower left and upper left electron detectors 8a and 8b.

Further, the signal processor 30 adds two adjacent detection signals together to generate an image data piece (SEM image) in an intermediate direction between the adjacent two of the electron detectors 8a to 8d. For example, the signal processor 30 adds together the detection signal ch1 from the lower left electron detector 8a and the detection signal ch2 from the upper left electron detector 8b to generate a left image a5, and adds together the detection signal ch3 from the upper right electron detector 8c and the detection signal ch4 from the lower right electron detector 8d to generate a right image a6.

Further, the signal processor 30 adds the detection signals ch1 to ch4 altogether to generate an full added image a9. Like an SEM image taken by a general scanning electron microscope, the full added image a9 shows edges in any orientation have high intensities and exhibits almost no brightness subtraction in edge orientation.

The image data pieces generated by the signal processor 30 are stored in the storage unit 23 shown in FIG. 1, and some images are replaced with brightness signals to be displayed by the image display unit 24.

The electron scanner 10, the signal processor 30, the image display unit 24, and the storage unit 23 are controlled by the controller 20. The controller 20 is provided with a profile creator 21 and an edge detector 22 which are provided for detecting the width of an edge of the pattern and an inclination angle of the edge.

The profile creator 21 extracts image data pieces in a designated region and extracts a distribution (a line profile) of brightness values along a line in a certain direction from the image data pieces.

The edge detector 22 detects the width of the edge of the pattern based on the line profile created by the profile creator 21. The edge detector 22 further calculates the inclination angle of the edge based on the detected edge width and a known height of the pattern.

Next, a description is given of the first algorithm provided so that the scanning electron microscope 100 in FIG. 1 can measure the width and the inclination angle of an edge of a pattern.

(First Algorithm)

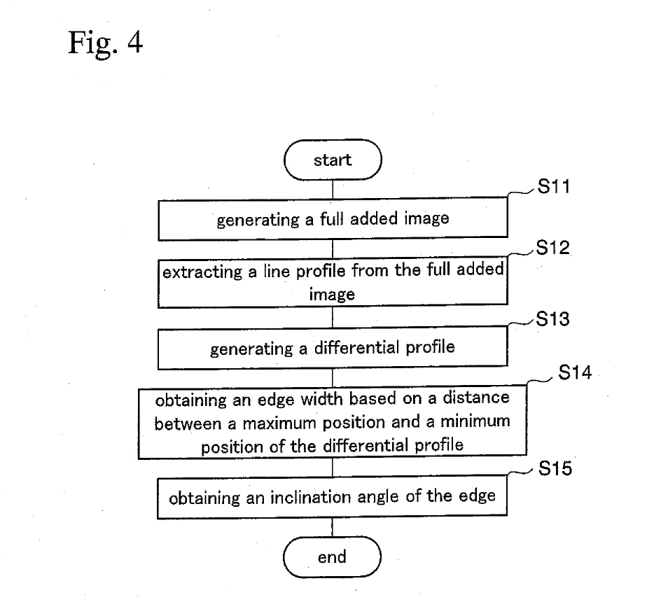

FIG. 4 is a flowchart showing the first algorithm.

Firstly, in Step S11 in FIG. 4, the signal processor 30 generates the full added image a9 in an observation region 71 of a surface of the sample 7.

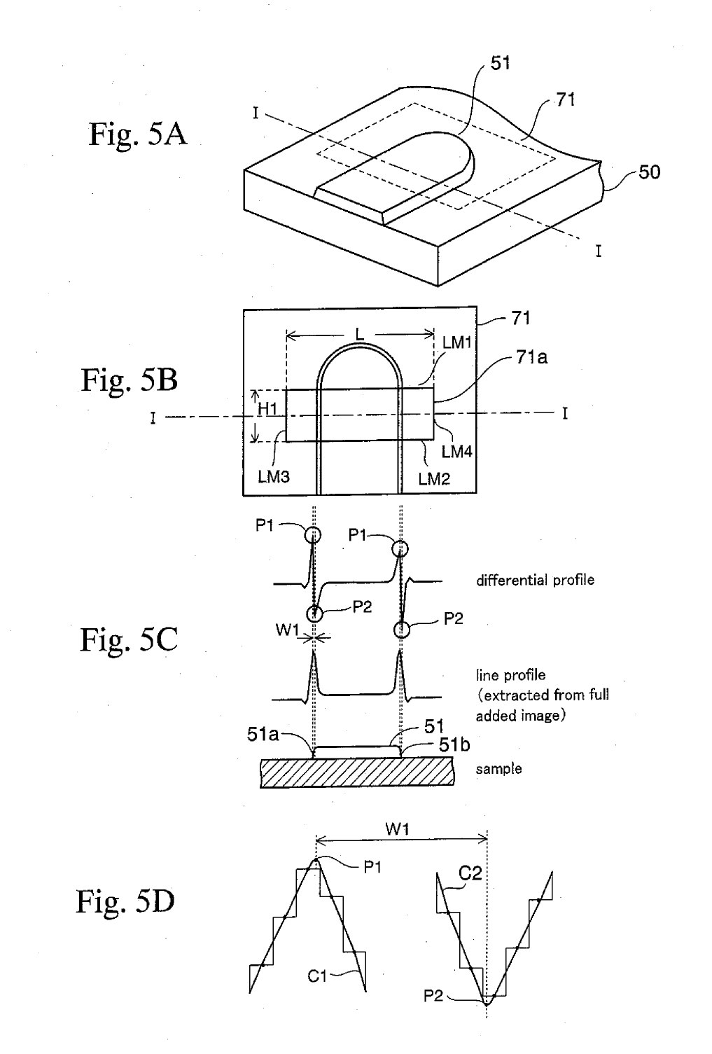

FIG. 5A is a perspective view showing an example of the sample 7. As illustrated therein, the sample 7 herein includes a photo mask substrate 50 and a line pattern 51 formed on the photo mask substrate 50. Inclined edges (a side walls) are formed around the line pattern 51. In FIG. 5A, a portion surrounded by a broken line is the observation region 71 scanned by the scanning electron microscope 100 by using the electron beam 9.

In Step S11, the scanning electron microscope 100 scans the observation region 71 in FIG. 5A by using the electron beam 9, and the signal processor 30 adds signals from the electron detectors 8a to 8d together to generate the full added image a9 as shown in FIG. 5B.

Next, in Step S12 in FIG. 4, the profile creator 21 of the controller 20 extracts a line profile from the full added image a9.

As shown in FIG. 5B, an inspection region 71a is herein set which is a region including a vicinity of each of the edges obtained by limiting the observation region 71. The inspection region 71a has a width H1 of 400 pixels, for example, and a length L. The inspection region 71a is selected by the operator by using an upper line marker LM1, a lower line marker LM2, a left line marker LM3, and a right line marker LM4.

Next, the profile creator 21 divides an image of the extracted inspection region 71a into a plurality of regions in a direction H1, and extracts a brightness distribution (a line profile) in a I-I line direction from pixel data in the divided regions. Note that when the line profile is obtained, the noise content may be reduced by performing smoothing processing based on, for example, a 3-pixel width in a direction of a length L.

An example of the line profile extracted from the inspection region 71a in FIG. 5B is shown in a middle part of FIG. 5C. As illustrated therein, the line profile extracted from the full added image a9 shows that peaks of brightness values appear in edge portions of the pattern and that the brightness values drastically change at the peaks.

Next, in Step S13 in FIG. 4, the edge detector 22 of the controller 20 differentiates the line profile to generate a differential profile.

An example of the differential profile is shown in an upper part of FIG. 5C. As illustrated therein, the differential profile has the maximum values corresponding to rising portions and the minimum values corresponding to descending portions of the peaks of the line profile.

Next, in Step S14 in FIG. 4, the edge detector 22 detects a position P1 of each maximum value and a position P2 of each minimum value from the differential profile. The edge detector 22 obtains a distance between the position P1 of the maximum value and the position P2 of the minimum value, as an edge width.

When being detected, the positions P1 and P2 of the maximum and minimum values of the differential profile may be obtained more accurately by obtaining derivative wave forms C1 and C2 in which pixels are interpolated as in FIG. 5D by using a plurality of derivative signals before and after each peak.

Further, the aforementioned edge width detection processing is performed in each divided region to obtain an average value of the edge widths calculated for the regions. Thereby, a more accurate edge width W1 is obtained.

Then, processing moves to Step S15 in FIG. 4. The edge detector 22 obtains an inclination angle θ of the edge as θ=tan⁻¹(H/W1) based on the edge width W1 and a known pattern height H, and then ends the first algorithm.

As described above, in the first algorithm, the line profile is extracted from the full added image a9, and the differential profile is obtained by differentiating the line profile. Then, the edge width and the edge inclination angle are detected based on the distance between the maximum value and the minimum value of the differential profile.

However, the width of the peak appearing in the edge portion of the line profile of the full added image a9 is never smaller than the diameter of the primary electron beam 9. Thus, the first algorithm does not make it possible to accurately obtain an edge width smaller than the diameter of the primary electron beam 9.

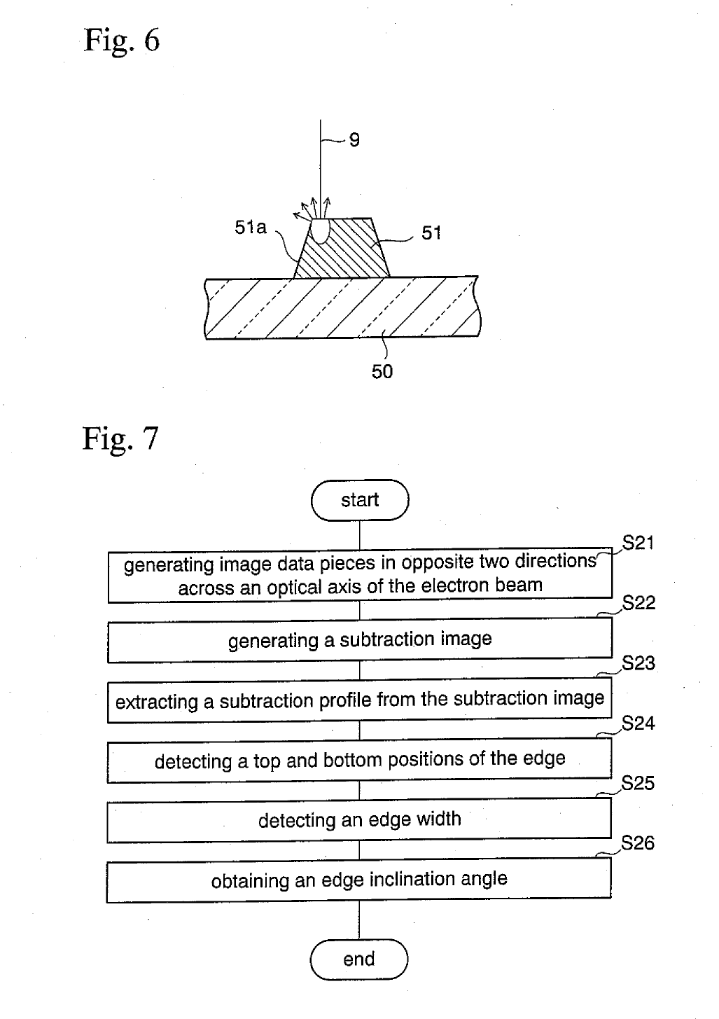

In addition, as shown in FIG. 6, a phenomenon occurs in which secondary electrons generated inside the pattern 51 are dispersed and reach an upper end of an edge 51a despite the primary electron beam 9 is away from the edge 51a, and secondary electrons are emitted from the upper end of the edge 51a of the pattern 51 at high brightness. Thereby, even though the edge width is larger than the diameter of the primary electron beam 9, an edge width larger than an actual edge width is detected, and thus the edge width and an edge inclination angle cannot be measured accurately.

Hence, the second algorithm will be described which is capable of measuring an edge width and an edge inclination angle more accurately than the first algorithm is.

(Second Algorithm)

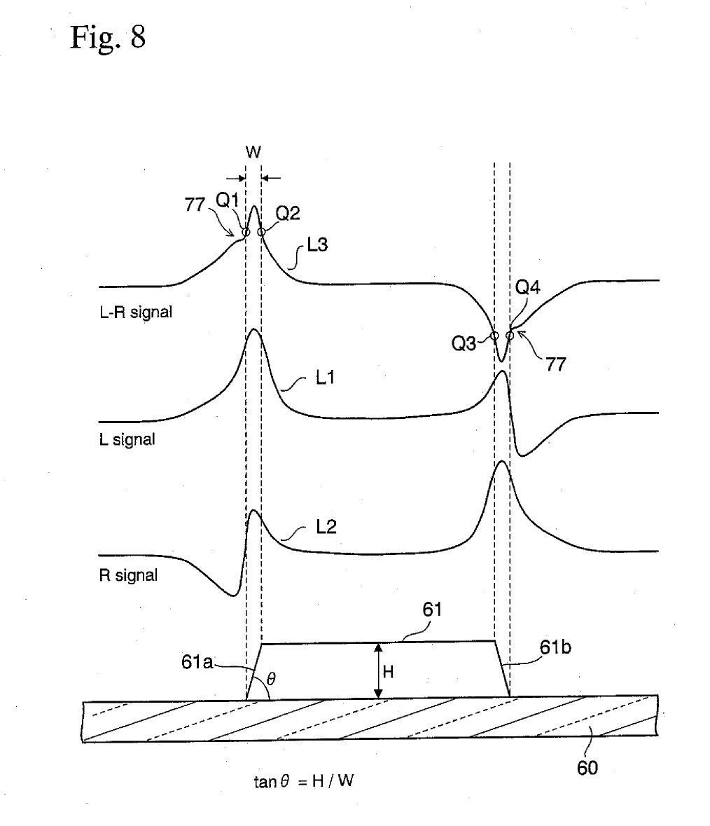

FIG. 7 is a flowchart showing the second algorithm. FIG. 8 is a schematic diagram showing a relationship among signal waveforms generated based on the second algorithm and edges of a pattern.

Firstly, in Step S21 in FIG. 7, the signal processor 30 of the scanning electron microscope 100 generates image data pieces in opposite two directions across an optical axis of the electron beam 9. The signal processor 30 herein generates image data pieces in the two directions each orthogonal to a direction in which a detection target edge of the pattern extends.

For example, as shown in a lower part of FIG. 8, when a pattern 61 extending in a direction perpendicular to the drawing plane is formed on a substrate 60, the signal processor 30 generates images from electron detectors arranged in the right and left directions with respect to the drawing plane. Herein, an image taken from the left side is the left image a5, and an image taken from the right side is the right image a6.

Next, in Step S22 in FIG. 7, the signal processor 30 generates a differential image by taking a subtraction between the two images generated in Step S21. In the case of FIG. 8, the signal processor 30 generates a differential image based on a subtraction between the left image a5 and the right image a6.

Next, the processing moves to Step S23 in FIG. 7, and the profile creator 21 of the controller 20 extracts a distribution of differential values along a line orthogonal to the pattern extending direction from the generated differential image and thereby generates a subtractive profile.

Note that the generation of the differential image in Step S22 may be omitted. In this case, as shown in FIG. 8, line profiles L1 and L2 are extracted from the left image a5 and the right image a6, respectively, and a subtractive profile L3 is obtained based on a subtraction therebetween.

In the case of FIG. 8, a subtractive profile L3 (a L-R signal) as shown in the upper part in FIG. 8 is thereby obtained. Meanwhile, in a subtractive profile, flat regions of surfaces of the substrate 60 and the pattern 61 represent differential values near zero. An inclination 61a on the left side represents a differential value emphasized on a positive side, while an inclination 61b on the right side represents a differential value emphasized on a negative side. As described above, in the subtractive profile, signals from the edges 61a and 61b on the surface of the sample are emphasized, and signals from the flat regions are nullified. Further, spread of a white band generated by the dispersion of the secondary electrons near upper ends of the edges 61a and 61b is erased by taking a subtraction between the left image and the right image.

In such a subtractive profile, a step 77 reflecting a subtraction in rate of change between a L signal L1 and a R signal L2 appears near each of the edges 61a and 61b, and a peak of the subtractive profile appears as a portion exceeding the step 77. The width of the peak (the portion exceeding the step 77) of the subtractive profile reflects the width of each of the edges 61a and 61b of the pattern 61. Even if the width of a pattern is smaller than the diameter of the primary electron beam 9, the width of the peak has a favorable correlation with the width of each of the edges 61a and 61b.

Hence, in Step S24 which is the next step (see FIG. 7), the edge detector 22 of the controller 20 differentiates the subtractive profile and detects positions of the maximum and minimum values of derivatives near peaks corresponding to the edges.

For example, in the subtractive profile L3 in FIG. 8, the maximum values of the derivatives are detected as positions Q1 and Q4, respectively, and the minimum values of the derivatives are detected as positions Q2 and Q3.

Next, in Step S25 in FIG. 7, the edge detector 22 detects edge widths W based on distances each between the detected positions of the corresponding maximum and minimum values of the derivatives in Step S24. In FIG. 8, a distance between the positions Q1 and Q2 of the maximum and minimum values of the derivatives is detected as the width W of the left edge 61a, and a distance between the positions Q3 and Q4 of the minimum and maximum values of the derivatives is detected as the width W of the right edge 61b.

Subsequently, in Step S26 in FIG. 7, the edge detector 22 obtains an inclination angle θ of each edge as θ=tan⁻¹(H/W) based on the edge width W detected in Step S25 and a pattern height H obtained in advance by another method or the like.

As described above, the second algorithm uses the subtractive profile of the signals (the images) in the opposite two directions across the optical axis of the electron beam. This makes it possible to extract information from an edge of a pattern and remove influence of the spread of the white band generated near the upper end of the edge due to the dispersion of the electron beam. In addition, even if the width of the edge of the pattern is smaller than the diameter of the electron beam, the edge inclination angle can be detected with high accuracy.

### Experimental Example 1

A description is given below of Experimental Example 1 in which a correlation between a peak and an inclination angle of an edge in a differential image and a subtractive profile based on image data pieces in opposite two directions across the optical axis of the electron beam.

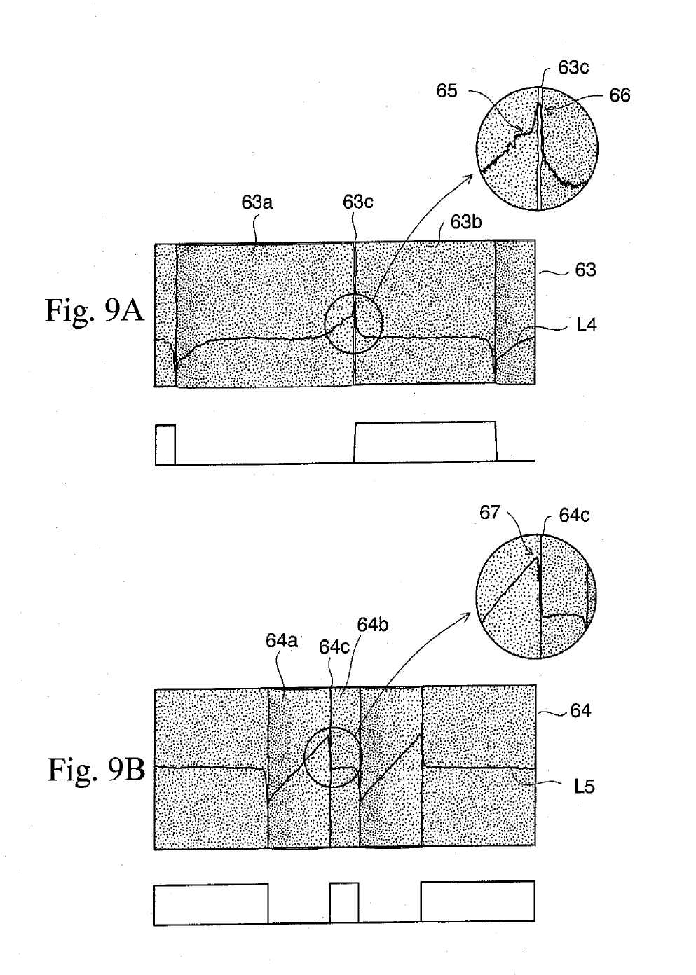

FIG. 9A shows a differential image and a line profile of a line/space pattern (sample) 63 having inclined edges. The sample 63 in FIG. 9A has a line pattern formed on a glass substrate, the line pattern being formed of a chromium film having a thickness of about 70 nm. A region 63a in FIG. 9A corresponds to a space portion, and a region 63b corresponds to a line pattern portion.

In the differential image as illustrated therein, a portion corresponding to a left edge of the line pattern 63b is shown in white at high brightness, and a portion corresponding to a right edge of the line pattern 63b is shown in black at lower brightness. Focusing on a subtractive profile L4, a step 65 appears in the portion corresponding to the left edge as shown in a partial enlarged diagram. A peak 66 protruding from the step 65 in a range of a width of about several nanometers is observed adjacent to the step 65.

FIG. 9B shows a differential image and a line profile of a line/space pattern (sample) 64 having perpendicular edges. A region 64a in FIG. 9B corresponds to a space portion, and a region 64b corresponds to a line pattern portion.

Also in the pattern 64b having the perpendicular edges as illustrated therein, a portion corresponding to a left edge of the pattern 64b is shown in white at high brightness, and a portion corresponding to a right edge of the pattern 64b is shown in black at lower brightness.

However, focusing on a subtractive profile L5, no step appears near the edges as shown in a partial enlarged diagram and no peak portion protruding from a step appears, either. This shows that reflection of an edge inclination angle of 90° and an edge width of approximately zero results in a peak width of zero as well, and thus a peak disappears.

The results in FIGS. 9A and 9B prove that the width of a peak protruding from a step in the subtractive profile has a correlation with an edge width of a pattern.

As described above, in the second algorithm, the edge width is obtained by detecting the step near the edge and the peak in the subtractive profile. In an actual inspection, however, an image of observation of a sample surface might include high noise content.

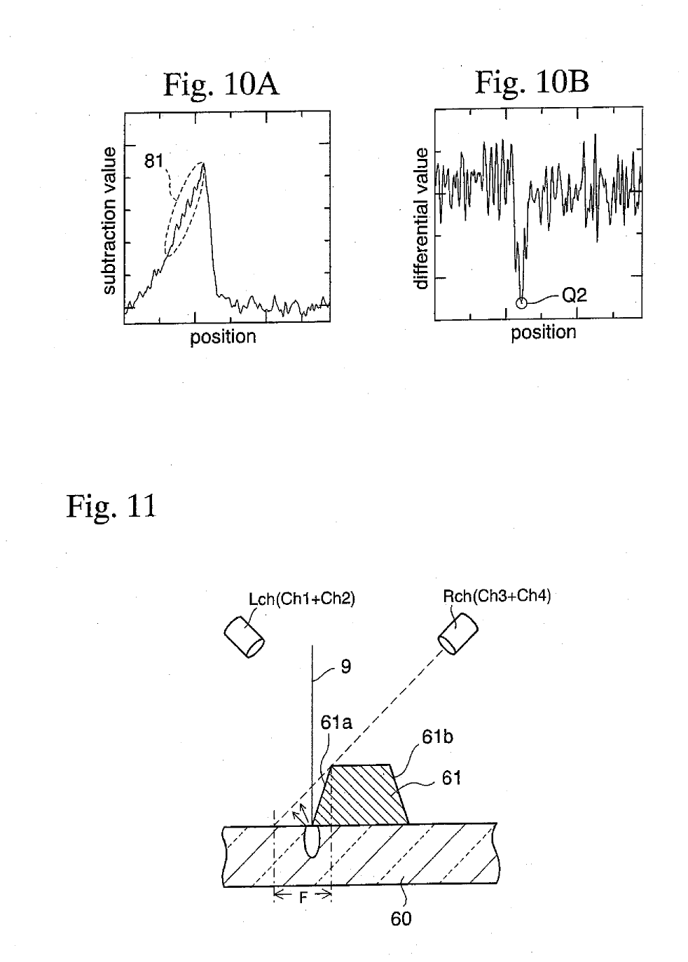

FIGS. 10A and 10B are graphs showing examples of a subtractive profile near an edge and a differential profile of the subtractive profile.

A plurality of teeth due to the noise content appear in a rising portion 81 of the subtractive profile shown in FIG. 10A. This makes it difficult to discriminate between a step due to an edge width and a tooth (a step) due to the noise content.

When the subtractive profile in FIG. 10A is differentiated, a differential profile as shown in FIG. 10B is obtained. With the differential profile in FIG. 10B, the position Q2 (the position of the upper end of the edge) of the minimum value of the derivatives can be detected clearly. A position of the maximum value of the derivatives, however, is hidden in the noise content, and thus the maximum value (the position of the lower end of the edge) is difficult to detect.

When an image data piece includes the high noise content as described above, the lower end of the edge is difficult to detect. In addition, as an edge width becomes smaller with the increase of an edge inclination angle, a step and a peak generally become smaller. The detection of the edge width is easily influenced by the noise and thus made difficult.

FIG. 11 is a schematic diagram for explaining why the lower end of the edge is difficult to detect in the subtractive profile.

As shown in FIG. 11, the subtractive profile is obtained as a subtraction between an electron detector Lch on the left side of the pattern 61 and an electron detector Rch on the right side. Here, a signal of the right electron detector Rch is focused. In a case where a range shown by the arrow F is irradiated with the primary electron beam 9, the secondary electrons generated from a surface of a sample are blocked by the pattern 61, and are less likely to reach the right electron detector Rch. For this reason, the range shown in the arrow F represents a shadow portion having low brightness in the right image a6. In the shadow portion, almost no information on a vicinity of the lower end of the left edge 61a can be obtained from a signal from the electron detector Rch, and a noise ratio is relatively increased in the portion. Thus, when the subtractive profile is generated based on the electron detectors Lch and Rch, the noise ratio of the subtractive profile is relatively increased near the lower end of the edge 61a. The same phenomenon also occurs on the right edge 61b of the pattern 61.

Hence, in the case of the high noise ratio, the third algorithm to be described below is used to detect the width of a pattern.

(Third Algorithm)

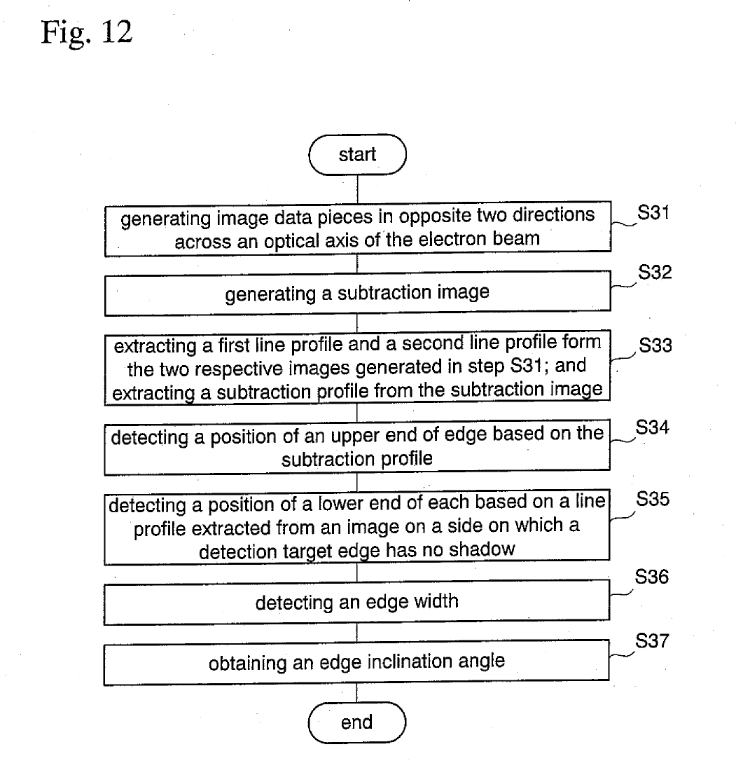

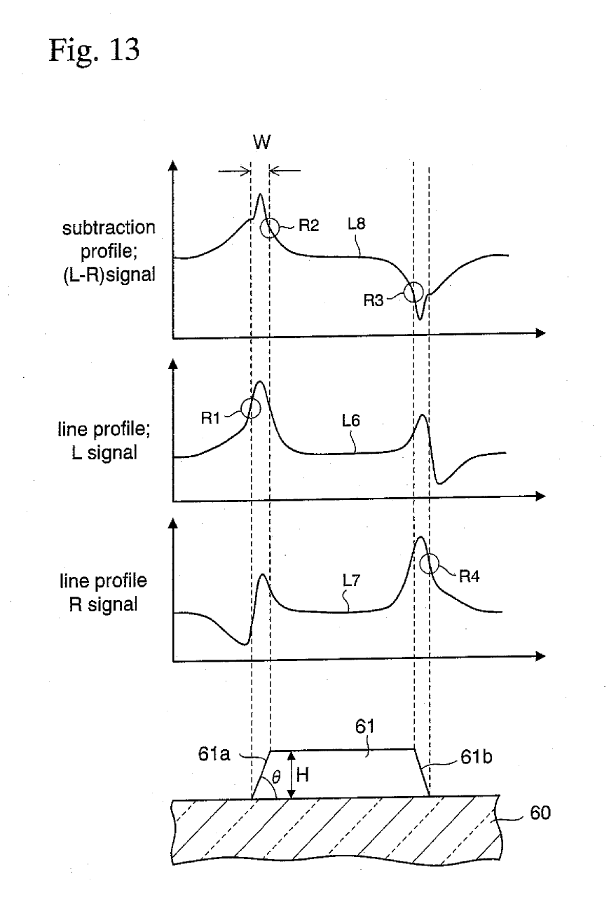

FIG. 12 is a flowchart showing the third algorithm. FIG. 13 is a schematic diagram showing a relationship among signal waveforms generated based on the third algorithm and edges of a pattern.

Firstly, in Step S31 in FIG. 12, the signal processor 30 of the scanning electron microscope 100 generates image data pieces in opposite two directions across the optical axis of the electron beam 9. For example, as in a sample in FIG. 13, when a pattern 61 extending in the direction perpendicular to the drawing plane is formed on a substrate 60, the signal processor 30 generates an image (a left image a5) taken from the left side of the drawing plane and an image (a right image a6) taken from the right side.

Next, in Step S32 in FIG. 12, the signal processor 30 generates a differential image by taking a subtraction between the images generated in the two directions in Step S31.

Next, the processing moves to Step S33, the profile creator 21 of the controller 20 extracts a first line profile L6 (a L signal) and a second line profile L7 (a R signal) from the two respective images generated in Step S31. The profile creator 21 also extracts a subtractive profile L8 (a L-R signal) from the differential image generated in Step S32.

Note that the generation of the differential image in Step S32 may be omitted. In this case, a subtraction between the line profiles L6 and L7 extracted in Step S33 are taken to obtain the subtractive profile L8.

Next, in Step S34 in FIG. 12, the edge detector 22 of the controller 20 detects a position of an upper end of each edge based on the subtractive profile L8 extracted in Step S34.

The edge detector 22 herein obtains derivatives of the subtractive profile L8 in FIG. 13 and detects a position R2 of the minimum value of the derivatives as a position of an upper end of the left edge 61a and a position R3 of the minimum value of the derivatives as a position of an upper end of the right edge 61b.

Next, in Step S35 in FIG. 12, the edge detector 22 detects a position of a lower end of each edge based on a line profile extracted from an image on a side (hereinafter, referred to as a no-shadow side) on which a detection target edge has no shadow.

For example, when the detection target edge is the left edge 61a in FIG. 13, the edge detector 22 prepares a signal on the no-shadow side of the left edge 61a, in other words, prepares the line profile L6 (the L signal) extracted from the left image a5. Then, the edge detector 22 differentiates the line profile L6 to thereby obtain a position R1 of the maximum value of the derivatives near the left edge 61a. The edge detector 22 detects the position R1 of the maximum value of the derivatives as a position of a lower end of the left edge 61a.

When the detection target edge is the right edge 61b, the edge detector 22 prepares the line profile L7 (the R signal) extracted from the right image a6. Then, the edge detector 22 differentiates the line profile L7 to thereby obtain a position R4 of the minimum value of the derivatives near the right edge 61b. The edge detector 22 detects the position R4 of the minimum value of the derivatives as a position of a lower end of the right edge 61b.

As described above, in Step S35 (see FIG. 12), the edge detector 22 detects the position of the lower end of the edge based on the line profile extracted from the image on the no-shadow side. Such line profile extracted from the image on the no-shadow side includes information on a portion from a side surface of the edge to the lower end thereof. Thus, the line profile has a lower ratio of noise content than in the case of using the subtractive profile L8, and the position of the lower end of the edge can be accurately detected.

Next, in Step S36 in FIG. 12, the edge detector 22 detects an edge width W based on the upper and lower end positions of the edge detected in Step S34 and Step S35, respectively.

In Step S37, the edge detector 22 obtains an edge inclination angle θ according to θ=tan⁻¹(H/W) based on the edge width W detected in Step S36 and the pattern height H obtained by being measured beforehand by another method. Then, the third algorithm ends.

As described above, according to the third algorithm, the upper end position of the edge is obtained based on the subtractive profile, and the lower end position of the edge is obtained based on the line profile extracted from the image on the no-shadow side. Thereby, even when the subtractive profile includes a high ratio of noise content and when a small edge width causes a step and a peak which are small in the subtractive profile, the edge width and the edge inclination angle can be obtained accurately.

### Experimental Example 2

A description is given of Experimental Example 2 in which the first algorithm, the third algorithm, and a SEM observation of cross-sections of patterns are used as three methods to obtain edge inclination angles of edges of the patterns.

Firstly, samples of isolated line patterns were prepared. The line patterns were formed on a glass substrate at a plurality of positions and had a thickness of about 84 nm and a width of about 200 nm. Line patterns (a first sample and a second sample) at different two positions on the glass substrate were selected to measure edge inclination angles thereof.

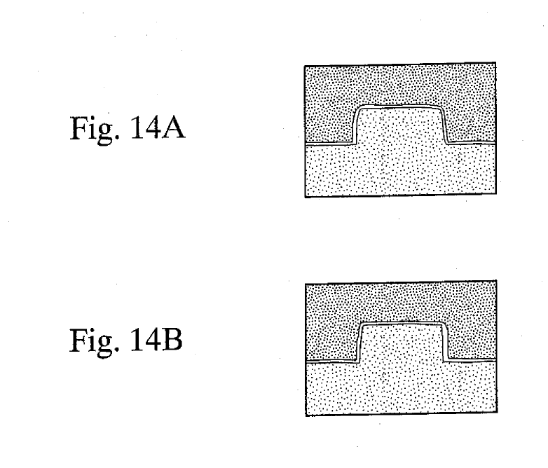

FIGS. 14A and 14B are diagrams showing results of observing cross-sections of the samples used in this experimental example by using a high-resolution scanning electron microscope.

After the cross-section of the first sample was observed, a SEM image as in FIG. 14A was obtained. From the image, inclination angles θ of 84.4° and 83.4° were respectively obtained for left and right edges of the first sample.

After the cross-section of the second sample was observed, a SEM image as in FIG. 14B was obtained. From the image, inclination angles θ of 87.4° and 86.9° were respectively obtained for left and right edges of the second sample.

Next, a description is given of results of obtaining edge inclination angles of the first sample according to the first and third algorithms.

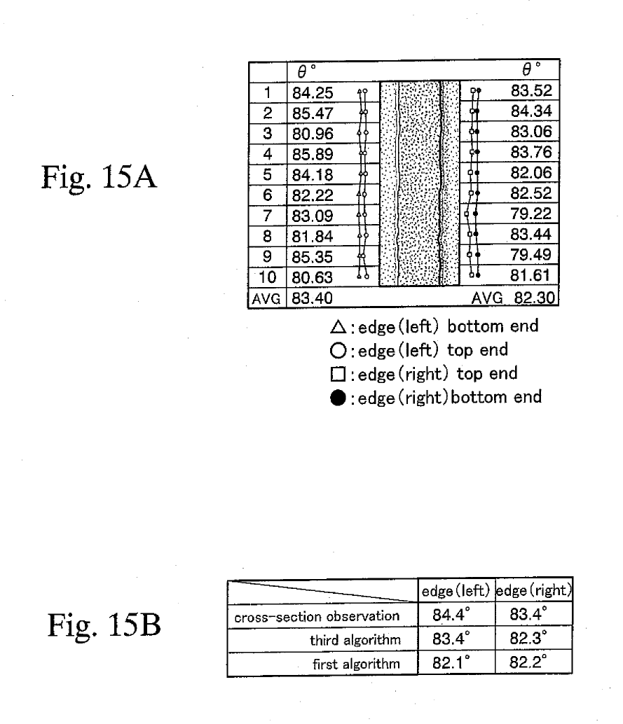

FIG. 15A is a schematic chart showing results of detecting the edge inclination angles of the first sample in Experimental Example 2 according to the third algorithm.

As in a SEM image in the central part of FIG. 15A, the line pattern of the first sample has variation in edge position in a width direction of the line pattern. Hence, in this Experimental Example, the line pattern was divided into ten small regions in a longitudinal direction thereof, and line profiles and a subtractive profile were extracted for each region. Further, based on the extracted line profiles and the subtractive profile, positions of upper and lower ends of the edges and edge inclination angles θ° were obtained according to the third algorithm. Then, averages of the edge inclination angles θ° obtained for the regions were obtained, and thereby edge inclination angles of the first sample were obtained.

The third algorithm showed results that left and right edges of the first sample respectively have inclination angles of 83.4° and 82.3°.

Thereafter, edge inclination angles of the first sample were obtained according to the first algorithm.

FIG. 15B is a chart showing results of obtaining the edge inclination angles of the first sample according to the first algorithm, together with the results of obtaining the edge inclination angles according to the cross-section observation and the third algorithm.

As shown in FIG. 15B, the first algorithm exhibits smaller edge inclination angles than the other methods. It is proved that that a larger edge width than an actual one is detected. The third algorithm provides the edge inclination angles closer to the cross-section observation results than those according to the first algorithm. It is proved that the edge width and the edge inclination angles can be measured more accurately according to the third algorithm than the first algorithm.

Next, a description is given of results of obtaining edge inclination angles of the second sample according to the first and third algorithms.

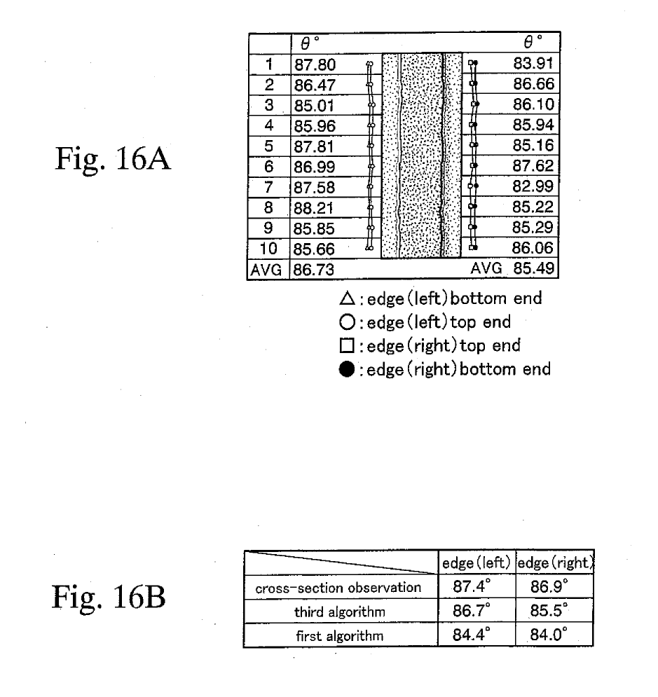

FIG. 16A is a schematic chart showing results of detecting the edge inclination angles of the second sample in Experimental Example 2 according to the third algorithm. FIG. 16B is a chart showing results of obtaining the edge inclination angles of the second sample according to the first algorithm, together with the results of obtaining the edge inclination angles according to the cross-section observation and the third algorithm.

As illustrated therein, according to the third algorithm, left and right edges of the second sample have inclination angles of 86.73° and 85.49°, respectively. In contrast, according to the first algorithm, the left and right edges of the second sample have inclination angles of 84.4° and 84.0°, respectively.

Also in the second sample, the third algorithm provides the edge inclination angles closer to the cross-section observation results than those according to the first algorithm. It is proved that the edge width and the edge inclination angles can be measured more accurately according to the third algorithm than the first algorithm.

Next, four patterns formed on a glass substrate at different positions were used to check variation of measurement results obtained according to the first and third algorithms.

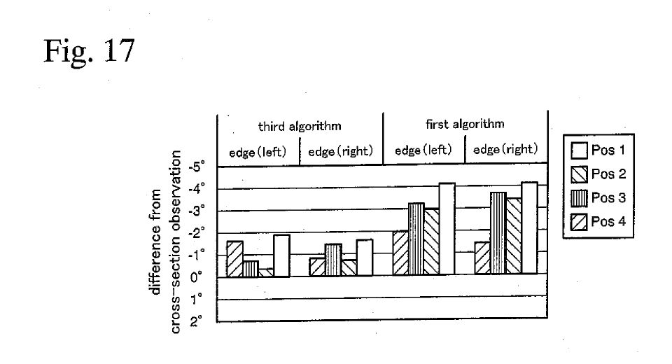

FIG. 17 is a diagram showing the measurement results obtained according to the first and third algorithms as subtractions from measurement results obtained by observing cross-sections of the patterns.

As shown in FIG. 17, edge inclination angles obtained according to the third algorithm have closer values to the measurement results obtained by the cross-section observation than the edge inclination angles obtained according to the first algorithm. FIG. 17 shows that a variation range of the measurement results obtained according to the third algorithm is smaller than a variation range of the measurement results obtained according to the first algorithm.

The results prove that the third algorithm has smaller variation of measurement values than the first algorithm does and makes it possible to measure edge inclination angles of a pattern more accurately.

What is claimed is:

1. A pattern measurement apparatus comprising:
an electron scanner scanning an observation region of a surface of a sample with an electron beam while irradiating the observation region with the electron beam;
a plurality of electron detectors arranged around an optical axis of the electron beam and detecting electrons emitted from the surface of the sample with irradiation of the electron beam;
a signal processor generating a plurality of image data pieces of the observation region which are taken in different directions, on the basis of detection signals of the electron detectors;
a profile creator extracting line profiles of a pattern formed on the sample from two of the image data pieces in opposite two directions across the optical axis and generating a subtractive profile of a subtraction between the line profiles extracted from the image data pieces in the two directions; and
an edge detector detecting a position of an upper end of an edge of the pattern on the basis of the subtractive profile and detecting a position of a lower end of the edge on the basis of the line profile extracted from any one of the image data pieces in the two directions.

2. The pattern measurement apparatus according to claim 1, wherein the edge detector detects the position of the lower end of the edge on the basis of the line profile extracted from the image data piece in the direction in which no shadow of the edge is generated.

3. The pattern measurement apparatus according to claim 2, wherein the edge detector detects a position of the minimum value of derivatives of the subtractive profile as the position of the upper end of the edge.

4. The pattern measurement apparatus according to claim 3, wherein the edge detector detects the position of the lower end of the edge on the basis of a position of the minimum value or the maximum value of a differential profile obtained by differentiating the line profile.

5. The pattern measurement apparatus according to claim 4, wherein the edge detector detects a width of the edge on the basis of a distance between the position of the upper end of the edge and the position of the lower end of the edge.

6. The pattern measurement apparatus according to claim 5, wherein the edge detector calculates an inclination angle of the edge on the basis of the width of the edge and a height of the pattern.

7. A pattern measurement method for detecting amounts of electrons by using a plurality of electron detectors arranged around an optical axis of the electron beam, the electrons being emitted from a surface of a sample with irradiation of an electron beam, the pattern measurement method comprising the steps of:
generating image data pieces of the surface of the sample which are taken in a plurality of different directions on the basis of detection signals from the electron detectors;
extracting line profiles of a pattern formed on the sample on the basis of two of the image data pieces in opposite two directions across the optical axis;
generating a subtractive profile of a subtraction between the line profiles extracted from the image data pieces in the opposite two directions across the optical axis;
detecting a position of an upper end of an edge of the pattern on the basis of the subtractive profile; and
detecting a position of a lower end of the edge on the basis of the line profile extracted from any one of the image data pieces in the two directions.

8. The pattern measurement method according to claim 7, wherein the position of the lower end of the edge is detected on the basis of the line profile extracted from the image data piece in the direction in which no shadow of the edge is generated.

9. The pattern measurement method according to claim 8, wherein the position of the upper end of the edge is detected on the basis of a position of the minimum value of derivatives of the subtractive profile.

10. The pattern measurement method according to claim 9, wherein the position of the lower end of the edge is detected from a position of the minimum value or the maximum value of a differential profile obtained by differentiating the line profile.

11. The pattern measurement method according to claim 10, wherein a width of the edge is detected on the basis of a distance between the position of the upper end of the edge and the position of the lower end of the edge.

12. The pattern measurement method according to claim 11, wherein an inclination angle of the edge is calculated on the basis of the width of the edge and a height of the pattern.
